(19) United States
(12) Patent Application Publication
(10) Pub. No.: US 2014/0316726 A1
(43) Pub. Date: Oct. 23, 2014

(54) REFLECTOMETRY METHOD FOR DETECTING SOFT FAULTS IN AN ELECTRICAL CABLE, AND SYSTEM FOR IMPLEMENTING THE METHOD

(71) Applicant: Commissariat A L'Energie Atomique Et Aux Energies Alternatives, Paris Cedex (FR)

(72) Inventor: Maud Franchet, Veneux-Les-Sablons (FR)

(73) Assignee: Commissariat A L'Energie Atomique Et Aux Energies Alternatives, Paris Cedex (FR)

(21) Appl. No.: 14/353,260

(22) PCT Filed: Oct. 17, 2012
(86) PCT No.: PCT/EP2012/070540

§ 371 Date: Apr. 21, 2014

(30) Foreign Application Priority Data
Oct. 20, 2011 (FR) 1159481

(51) Int. Cl. G01R 31/11; G01R 31/08

(52) U.S. Cl. CPC G01R 31/11; G01R 31/088
USPC 702/59

(57) ABSTRACT

A reflectometry method for detecting faults in a cable, comprising a step of comprises acquiring a signal injected into the cable and reflected off at least one singularity of the cable, and the following steps:
decomposing the reflected signal into a plurality of time components,
constructing, from the time components, a plurality of intermediate signals,
calculating the Wigner-Ville transform, of each of the intermediate signals and of the reflected signal,
calculating a time-frequency transform equal to the sum of the Wigner-Ville transforms of the time components, based on a linear combination of the Wigner-Ville transforms of each of the intermediate signals and of the reflected signal,
detecting and locating the maxima of the time-frequency transform, and deriving the existence and the location of the sought faults therefrom.

The invention relates to a reflectometry method and system for detecting and localizing soft faults in a cable. The field of the invention is that of time-domain and/or frequency-domain reflectometry.

Known time-domain reflectometry systems conventionally operate in accordance with the following method. A known signal, for example a pulse signal or else a multicarrier signal, is injected into one end of the cable to be tested. The signal propagates along the cable and is reflected by singularities therein.

A singularity in a cable corresponds to a break in the propagation conditions of the signal in this cable. Singularities most often result from faults that locally modify the characteristic impedance of the cable, causing discontinuities in the linear parameters thereof.

The reflected signal is backpropagated to the injection point, and is then analyzed by the reflectometry system. The delay between the injected signal and the reflected signal allows a singularity in the cable, corresponding for example to an electrical fault, to be located.

The invention applies to any type of electric cable, particularly power transmission cables or communication cables, whether in fixed or mobile installations. The cables in question may be coaxial cables, twin-lead cables, parallel-line cables, twisted-pair cables or any other type of cable provided that it is possible to inject a reflectometry signal into it and to measure its reflection.

Known time-domain reflectometry methods are particularly suitable for detecting, in a cable, hard faults such as short circuits or open circuits or more generally any significant local modification in the impedance of the cable. Faults are detected by measuring the amplitude of the signal reflected therefrom; the harder the fault, the larger and therefore more detectable the amplitude of the detected signal.

In contrast, a soft fault, for example resulting from a superficial deterioration of the cable cladding, generates a low-amplitude peak in the reflected reflectometry signal and is consequently harder to detect using conventional time-domain methods.

This is why time-frequency reflectometry methods have been developed in order to allow better detection of low-amplitude reflected signals. Among these methods, mention may be made of that described in U.S. Pat. No. 7,337,079, which method is based on the application of a time-frequency Wigner-Ville transform to the signal reflected in the cable. This method enables better discrimination of signal reflections of soft faults, with good time and frequency resolution.

However, this transform belongs to the Cohen class of transforms and has a quadratic character, which means that its application to a multi-component signal results in the generation of additional undesirable terms called cross terms in the remainder of the text.

Such terms appear on the final reflectogram as amplitude peaks that may be confused with actual cable faults, possibly leading to false detection. Furthermore, these cross terms may also mask the existence of actual faults by superposing themselves on the amplitude peaks associated with the singularities of the cable.

A technical problem therefore exists, which problem consists in removing the influence of the cross terms resulting from the application of a Wagner-Ville transform to the signal reflected in the cable.

The article “The use of the pseudo Wigner Ville Transform for detecting soft defects in electric cables, Maud Franchet et al.” is known, which presents an adaptation of the Wigner-Ville transform using a windowing of the original transform in order to limit the influence of the cross terms. However, this method does not make it possible to completely suppress the appearance of undesirable amplitude peaks.

The article “Nonexistence of cross-term free time-frequency distribution with concentration of Wigner-Ville distribution, Zou Hongxing et al.” is also known, and discusses the problem of the appearance of cross terms, but also aims to demonstrate the impossibility of adapting the Wigner-Ville transform to totally suppress the cross terms.

The present invention thus aims at providing a time-frequency reflectometry method and system using the Wigner-Ville transform and enabling the suppression of the influence of cross terms, in order to guarantee correct detection of faults, in particular soft faults, in a cable being tested.

One subject of the invention is thus a reflectometry method for detecting at least one fault in a cable, comprising a step of acquiring a signal S(t) injected into said cable and reflected off at least one singularity of said cable, characterized in that it furthermore comprises the following steps:
Decomposing said reflected signal S(t) into a plurality of time components sᵢ(t),
Constructing, from said time components, a plurality of intermediate signals, (X_{iq}(t),Xᵢ(t)) using the following relation

$${X}_{i ( q )} ( t ) = α \cdot {s}_{i} \cdot δ ( t - {t}_{i} ) + {\sum }_{j = 1 , j \neq i}^{n} {s}_{j} \cdot δ ( t - {t}_{j} ) ,$$

for i varying from 1 to the number n of components of the signal S(t), with α a weighting coefficient equal to the complex number j the square of which is equal to −1 or equal to an nth root of unity

$${z}_{q} = {e}^{j \frac{2 q π}{n}} ,$$

with q varying from 1 to the integer part of n/2,
Calculating the Wigner-Ville transform, W_{Xi}, W_{S}, of each of said intermediate signals and of said reflected signal,
Calculating a time-frequency transform Tₛ(t,ω) equal to the sum of the Wigner-Ville transforms of said time components sᵢ(t), based on a linear combination of said Wigner-Ville transforms of each of said intermediate signals W_{Xi} and of said reflected signal W_{S},
Detecting and locating the maxima of said time-frequency transform Tₛ(t,ω), and deriving the existence and the location of the sought faults therefrom.

According to one particular aspect of the invention, when said weighting coefficient α is equal to an nth root of unity, the time-frequency transform Tₛ(t,ω) is given by the relation

$${T}_{s} ( t , ω ) = \frac{1}{2 \cdot ( P + 1 )} \{ {\sum }_{q = 1}^{P} {\sum }_{i = 1}^{n} {W}_{{X}_{iq}} - [ P \cdot ( n - 2 ) - 2 ] \cdot {W}_{s} \}$$

if n is even and by the relation

$${T}_{s} ( t , ω ) = \frac{1}{2. P + 1} \{ {\sum }_{q = 1}^{P} {\sum }_{i = 1}^{n} {W}_{{X}_{iq}} - [ P . ( n - 2 ) - 1 ] . {W}_{s} \}$$

if n is odd, with P an integer number equal to the integer part of n/2, W_{Xiq} the Wigner-Ville transform of the intermediate signal X_{iq}(t) and W_{S} the Wigner-Ville transform of the reflected signal S(t).

According to another particular aspect of the invention, when said weighting coefficient α is equal to the complex number j the square of which is equal to −1, the time-frequency transform Tₛ(t,ω) is given by the relation

$${T}_{s} ( t , ω ) = \frac{1}{n - 1} \{ {\sum }_{i = 1}^{n} {W}_{{X}_{i}} - ( n - 2 ) . {W}_{s} \} ,$$

with n an integer strictly greater than two, W_{Xi} the Wigner-Ville transform of the intermediate signal Xᵢ(t) and W_{S} the Wigner-Ville transform of the reflected signal S(t).

The decomposition of the signal S(t) into a plurality of time components sᵢ(t) may be carried out by sub-sampling.

It may also be carried out by decomposition of the signal into a linear combination of Gaussian functions.

It may also be carried out using the following relation:

$$s ( t ) = {\sum }_{i = 1}^{N} w ( t - {t}_{i} ) . s ( t ) ,$$

where w is a time window of given length applied to said signal s(t) at a plurality of successive times tᵢ.

In a variant embodiment, the method according to the invention furthermore comprises a step of calculating the normalized time-frequency cross-correlation function applied to the result of the time-frequency transform, Tₛ(t,ω).

In a variant embodiment of the invention, said reflected signal S(t) is denoised beforehand after its acquisition.

Another subject of the invention is a device for processing a reflectometry signal including means for acquiring a signal reflected off at least one singularity of a cable and processing and analyzing means adapted to implement the reflectometry method according to the invention.

Another subject of the invention is a reflectometry system comprising means for injecting a signal S(t) into a cable to be tested, means for acquiring said signal reflected off at least one singularity of said cable, means for analog-to-digital conversion of said reflected signal, characterized in that it furthermore comprises processing and analyzing means adapted to implement the reflectometry method according to the invention.

Other features and advantages of the invention will become apparent thanks to the following description, which is given with reference to the appended drawings, which comprise:

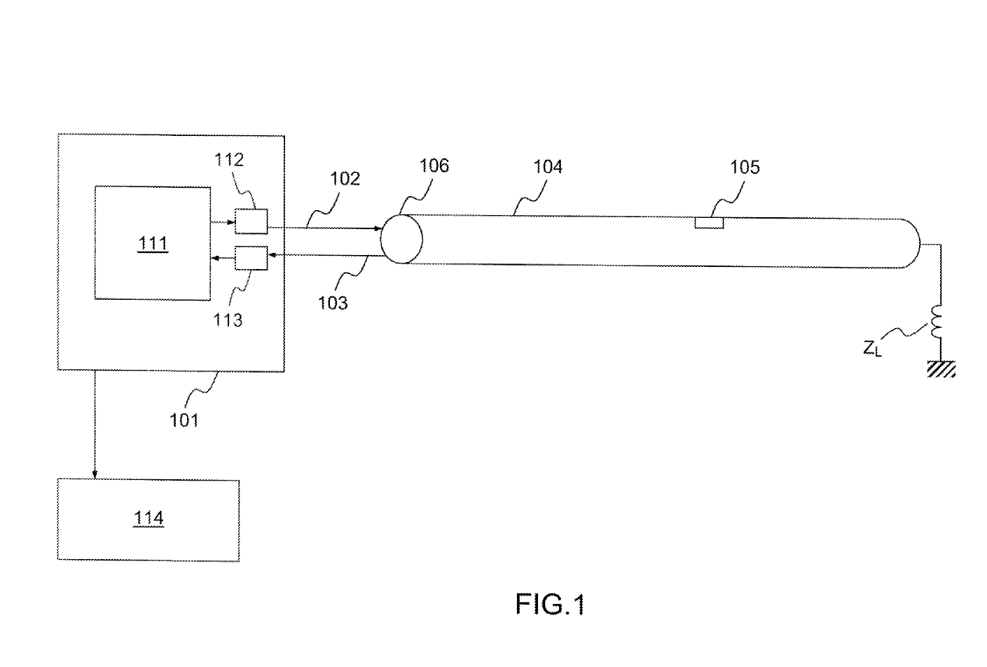

FIG. 1, a block diagram illustrating a reflectometry system according to the invention for detecting soft faults in a cable,

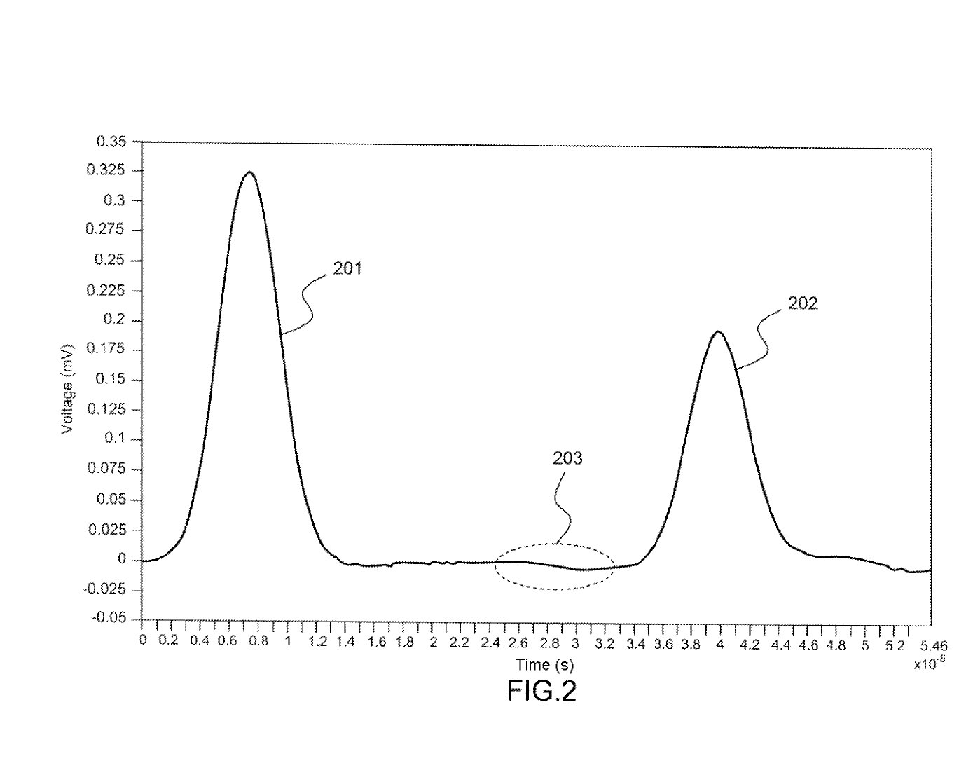

FIG. 2, a diagram of a time-domain reflectogram obtained for a cable with a soft fault,

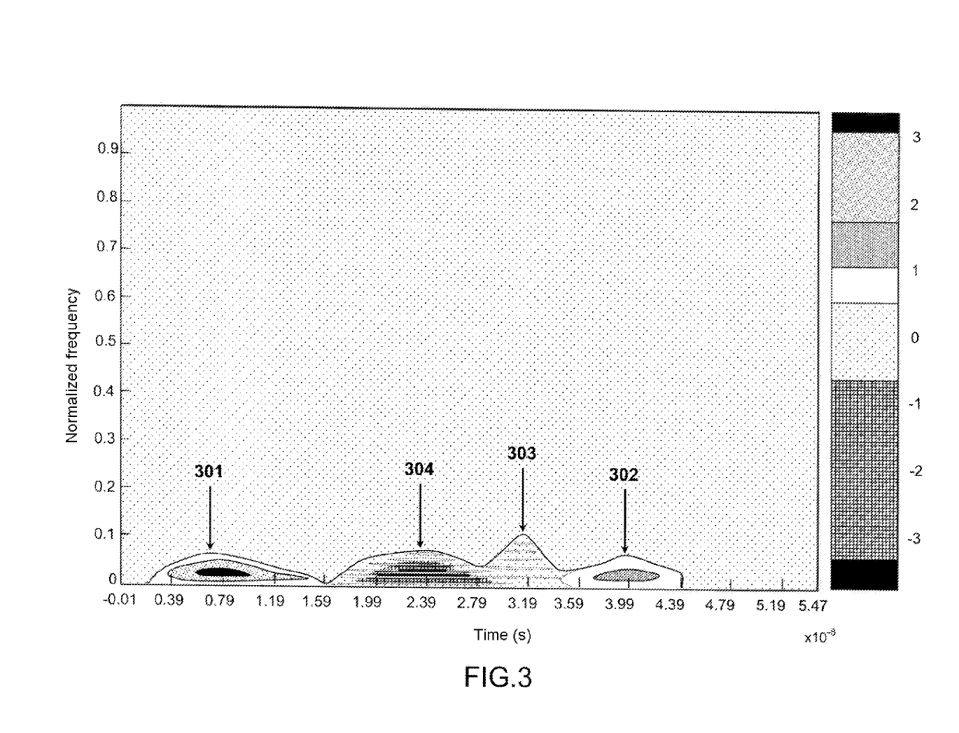

FIG. 3, a diagram of the Wigner-Ville transform obtained after application to the time-domain reflectogram in FIG. 2,

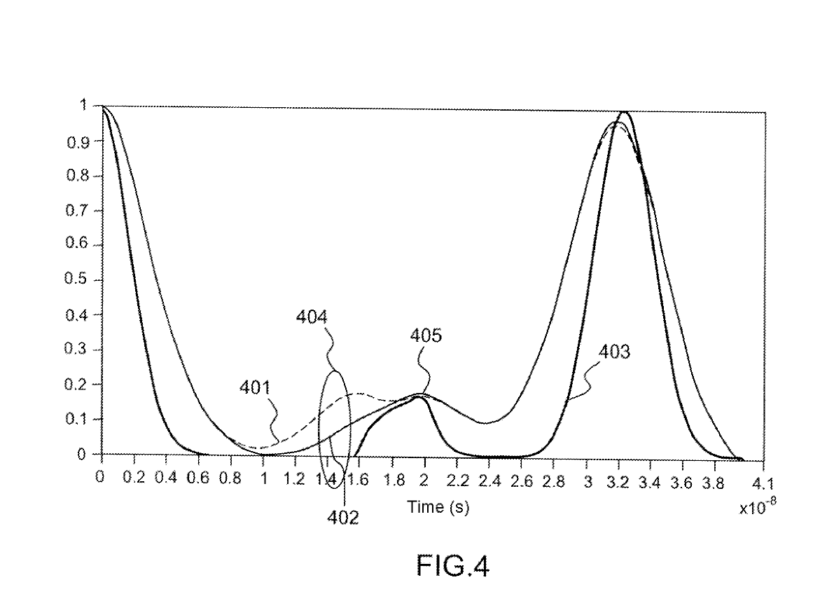

FIG. 4, a diagram of the normalized time-frequency cross-correlation function (NTFC) of the Wigner-Ville transform applied to the signal in FIG. 2, also illustrating comparative results obtained with two methods of the prior art and the method according to the invention.

The Wigner-Ville transform is part of the Cohen class of transforms. It is defined by the following relation, for a signal x(t):

$${W}_{x} ( t , ω ) = \frac{1}{2 π} {\int }_{- ∞}^{+ ∞} \overline{x} ( t - \frac{τ}{2} ) . x ( t + \frac{τ}{2} ) . {e}^{- j τ ω} d τ$$

Where x̅(t) denotes the conjugate of the signal x(t) and ω the angular frequency of the signal x(t).

Based on the Wigner-Ville transform defined above, it is possible to derive the “cross” Wigner-Ville transform, or cross Wigner distribution, of two signals x₁(t) and x₂(t):

$${W}_{{x}_{1} {x}_{2}} ( t , ω ) = \frac{1}{2 π} {\int }_{- ∞}^{+ ∞} \overline{{x}_{1}} ( t - \frac{τ}{2} ) . {x}_{2} ( t + \frac{τ}{2} ) . {e}^{- j τ ω} d τ$$

One of the major problems of this transform comes from its quadratic character. Indeed, if a signal appears in the form of a sum of n components, the Wigner-Ville transform will lead to the appearance not of n terms but of n(n−1)/2+n terms. To illustrate this, let us consider the two-component signal s(t) as defined in the relation (1). The Wigner-Ville transform of s(t) is given by equation (2). The cross term is equal to 2Re(Wₛ_{₁}ₛ_{₂}(t,ω))

s(t)=s₁(t)+s₂(t) (1)

Wₛ(t,ω)=Wₛ_{₁}(t,ω)+Wₛ_{₂}(t,ω)+2Re(Wₛ_{₁}ₛ_{₂}(t,ω)) (2)

One of the objectives of the invention is to provide an adapted time-frequency transform that no longer has any cross terms.

To illustrate the approach chosen to achieve the invention, we will now describe two examples of construction of an adapted Wigner-Ville transform for a two- or three-component signal s(t), respectively. These two examples are given for illustration purposes and to enable a better understanding of the invention. As will be explained further on in the description, the invention is preferably applied to a signal composed of a large number n of components that can, for example, each be set equal to a sample of the digitized signal.

### EXAMPLE FOR A TWO-COMPONENT SIGNAL

Let us first consider the case where the signal s(t) includes two components: s(t)=s₁(t)+s₂(t).

To eliminate the cross term identified with the relation (2), it is advisable to construct a time-frequency transform T(t,ω) which applied to the signal s gives as a result the sum of the Wigner-Ville transforms of the respective components s₁,s₂ i.e. Tₛ(t,ω)=Wₛ_{₁}(t,ω)+Wₛ_{₂}(t,ω). ω denotes the angular frequency of the signal in radians per second, which is directly connected to the frequency f of the signal by the known relation ω=2πf.

Now, the application of the Wigner-Ville transform to the signal s results in the following relation: Wₛ(t,ω)=Wₛ_{₁}(t,ω)+Wₛ_{₂}(t,ω)+Wₛ_{₁}ₛ_{₂}(t,ω)+Wₛ_{₂}ₛ_{₁}(t,ω).

Two signals are then defined x(t)=s₁(t)−s₂(t) and y(t)=s₁(t)+s₂(t). Each of the signals is then multiplied by its conjugate (cf. equations (3) and (4)).

x(t)· x̅(t)=s₁(t)· s̅₁̅(t)+s₂(t)· s̅₂̅(t)−(s₁(t) s̅₂̅(t)+s₂(t) s̅₁̅(t)) (3)

y(t)· y̅(t)=s₁(t)· s̅₁̅(t)+s₂(t)· s̅₂̅(t)−(s₁(t) s̅₂̅(t)+s₂(t) s̅₁̅(t)) (4)

The Wigner-Ville transforms of the two signals x(t) and y(t) are then deduced therefrom (cf. equations (5) and (6)).

Wₓ(t,ω)=Wₛ_{₁}(t,ω)+Wₛ_{₂}(t,ω)−(Wₛ_{₁}ₛ_{₂}(t,ω)+Wₛ_{₂}ₛ_{₁}(t,ω)) (5)

W_{y}(t,ω)=Wₛ_{₁}(t,ω)+Wₛ_{₂}(t,ω)−(Wₛ_{₁}ₛ_{₂}(t,ω)+Wₛ_{₂}ₛ_{₁}(t,ω)) (6)

The desired result is then obtained by summing the relations (5),(6) and the expression of the Wigner-Ville transform of the signal s(t) (cf. equations (7)).

$$\begin{matrix}{T}_{s} ( t , ω ) = {W}_{{s}_{1}} ( t , ω ) + {W}_{{s}_{2}} ( t , ω ) \\ = \frac{1}{4} ( {W}_{x} ( t , ω ) + {W}_{y} ( t , ω ) + 2 {W}_{s} ( t , ω ) )\end{matrix} \qquad ( 7 )$$

For a two-component signal, the adapted Wigner-Ville transform according to the invention is then equal to

$${T}_{s} = \frac{1}{4} ( {W}_{x} ( t , ω ) + {W}_{y} ( t , ω ) + 2 {W}_{s} ( t , ω ) ) .$$

By applying this transform to the signal s, the result obtained is the sum of the Wigner-Ville transforms of each component. The cross term has been suppressed.

### EXAMPLE FOR A THREE-COMPONENT SIGNAL

We now move on to the case of a three-component signal: s(t)=s₁(t)+s₂(t)+s₃(t).

To eliminate all the cross terms, it is necessary to construct an adapted Wigner-Ville transform Tₛ so as to obtain the following result:

Tₛ(t,ω)=Wₛ_{₁}(t,ω)+Wₛ_{₂}(t,ω)+Wₛ_{₃}(t,ω)

To do this, three signals are defined that are linear combinations of the three components of the signal s, where

$$z = {e}^{2 j \frac{π}{3}}$$

is the complex cube root of unity, i.e. the cube of z is equal to 1:

x(t)=z·s₁(t)+s₂(t)+s₃(t)

y(t)=s₁(t)+z·s₂(t)+s₃(t)

w(t)=s₁(t)+s₂(t)+z·s₃(t)

The products of these three signals x, y and w and their respective conjugates are then calculated (cf. equations 8, 9, 10)

$$\begin{matrix}x ( t ) . \overline{x} ( t ) = {\vert z \vert}^{2} {s}_{1} ( t ) . \overline{{s}_{1}} ( t ) + {s}_{2} ( t ) . \overline{{s}_{2}} ( t ) + {s}_{3} ( t ) . \overline{{s}_{3}} ( t ) + z . ( {s}_{1} ( t ) . \overline{{s}_{2}} ( t ) + {s}_{1} ( t ) . \overline{{s}_{3}} ( t ) ) + \overline{z} . ( {s}_{2} ( t ) . \overline{{s}_{1}} ( t ) + {s}_{3} ( t ) . \overline{{s}_{1}} ( t ) ) + {s}_{2} ( t ) . \overline{{s}_{3}} ( t ) + {s}_{3} ( t ) . \overline{{s}_{2}} ( t ) & ( 8 ) \\ y ( t ) . \overline{y} ( t ) = {s}_{1} ( t ) . \overline{{s}_{1}} ( t ) + {\vert z \vert}^{2} {s}_{2} ( t ) . \overline{{s}_{2}} ( t ) + {s}_{3} ( t ) . \overline{{s}_{3}} ( t ) + z . ( {s}_{2} ( t ) . \overline{{s}_{1}} ( t ) + {s}_{2} ( t ) . \overline{{s}_{3}} ( t ) ) + \overline{z} . ( {s}_{1} ( t ) . \overline{{s}_{2}} ( t ) + {s}_{3} ( t ) . \overline{{s}_{2}} ( t ) ) + {s}_{1} ( t ) . \overline{{s}_{3}} ( t ) + {s}_{3} ( t ) . \overline{{s}_{1}} ( t ) & ( 9 ) \\ w ( t ) . \overline{w} ( t ) = {s}_{1} ( t ) . \overline{{s}_{1}} ( t ) + {s}_{2} ( t ) . \overline{{s}_{2}} ( t ) + {\vert z \vert}^{2} . {s}_{3} ( t ) . \overline{{s}_{3}} ( t ) + z . ( {s}_{3} ( t ) . \overline{{s}_{1}} ( t ) + {s}_{3} ( t ) . \overline{{s}_{2}} ( t ) ) + \overline{z} . ( {s}_{1} ( t ) . \overline{{s}_{3}} ( t ) + {s}_{2} ( t ) . \overline{{s}_{3}} ( t ) ) + {s}_{1} ( t ) . \overline{{s}_{2}} ( t ) + {s}_{2} ( t ) . \overline{{s}_{1}} ( t ) & ( 10 )\end{matrix}$$

Their Wigner-Ville transforms are deduced therefrom, knowing that |z|²=1 (cf. equations 11, 12 and 13).

$$\begin{matrix}{W}_{x} ( t , ω ) = {W}_{{s}_{1}} ( t , ω ) + {W}_{{s}_{2}} ( t , ω ) + {W}_{{s}_{3}} ( t , ω ) + z . ( {W}_{{s}_{1} {s}_{2}} ( t , ω ) + {W}_{{s}_{1} {s}_{3}} ( t , ω ) ) + \overline{z} . ( {W}_{{s}_{2} {s}_{1}} ( t , ω ) + {W}_{{s}_{3} {s}_{1}} ( t , ω ) ) + {W}_{{s}_{2} {s}_{3}} ( t , ω ) + {W}_{{s}_{3} {s}_{2}} ( t , ω ) & ( 11 ) \\ {W}_{y} ( t , ω ) = {W}_{{s}_{1}} ( t , ω ) + {W}_{{s}_{2}} ( t , ω ) + {W}_{{s}_{3}} ( t , ω ) + z . ( {W}_{{s}_{2} {s}_{1}} ( t , ω ) + {W}_{{s}_{2} {s}_{3}} ( t , ω ) ) + \overline{z} . ( {W}_{{s}_{1} {s}_{2}} ( t , ω ) + {W}_{{s}_{3} {s}_{2}} ( t , ω ) ) + {W}_{{s}_{1} {s}_{3}} ( t , ω ) + {W}_{{s}_{3} {s}_{1}} ( t , ω ) & ( 12 ) \\ {W}_{w} ( t , ω ) = {W}_{{s}_{1}} ( t , ω ) + {W}_{{s}_{2}} ( t , ω ) + {W}_{{s}_{3}} ( t , ω ) + z . ( {W}_{{s}_{2} {s}_{1}} ( t , ω ) + {W}_{{s}_{2} {s}_{3}} ( t , ω ) ) + \overline{z} . ( {W}_{{s}_{1} {s}_{2}} ( t , ω ) + {W}_{{s}_{3} {s}_{2}} ( t , ω ) ) + {W}_{{s}_{1} {s}_{3}} ( t , ω ) + {W}_{{s}_{3} {s}_{1}} ( t , ω ) & ( 13 )\end{matrix}$$

The next step consists in summing the transforms of the three signals x,y,w (cf. equation 14).

Wₓ(t,ω)+W_{y}(t,ω)+W_{w}(t,ω)=3·(Wₛ_{₁}(t,ω)+Wₛ_{₂}(t,ω)+Wₛ_{₃}(t,ω))+(1+z+ z̅)·(Wₛ_{₁}ₛ_{₂}(t,ω)+Wₛ_{₁}ₛ_{₃}(t,ω)+Wₛ_{₂}ₛ_{₁}(t,ω)+Wₛ_{₃}ₛ_{₁}(t,ω)+Wₛ_{₂}ₛ_{₃}(t,ω)+Wₛ_{₃}ₛ_{₂}(t,ω)) (14)

Now 1+z+ z̅=0, therefore the adapted Wigner-Ville transform making it possible to obtain the desired result is obtained:

$$\begin{matrix}{T}_{s} ( t , ω ) = {W}_{{s}_{1}} ( t , ω ) + {W}_{{s}_{2}} ( t , ω ) + {W}_{{s}_{3}} ( t , ω ) \\ = \frac{1}{3} ( {W}_{x} ( t , ω ) + {W}_{y} ( t , ω ) + {W}_{w} ( t , ω ) )\end{matrix} \qquad ( 15 )$$

Adapted Wigner-Ville Transform According to the Invention for an n-Component Signal.

The examples described above for a two- or three-component signal can be generalized for an n-component signal, n being an integer greater than or equal to 2.

Beforehand a reminder is provided of the definition and the properties of the nth roots of unity.

The nth roots of unity are the solutions of the equation zⁿ=1, with z a complex number and n a strictly positive integer.

The solutions of this equation can be written in the form

$$z = {e}^{j \frac{2 k π}{n}}$$

for k varying from 0 to n−1.

The nth roots of unity have the following properties. If z is a solution of the equation zⁿ=1 then its conjugate is also a solution. It is deduced therefrom that if

$$z = {e}^{j \frac{2 k π}{n}}$$

with k varying from 1 to the integer part of n/2 is a solution, then

$$\overline{z} = {e}^{j \frac{2 ( n - k ) π}{n}}$$

is also a solution. The subset Sₚ of solutions of the equation is then defined. If n is even, Sₚ includes p=n/2 distinct elements. If n is odd, Sₚ includes p=(n−1)/2 distinct elements.

Another essential property of the nth roots of unity is that their sum is zero:

$${\sum }_{k = 0}^{n - 1} {e}^{j \frac{2 k π}{n}} = 0.$$

These properties will be used below to develop an adapted time-frequency transform for eliminating the cross terms of the Wigner-Ville transform.

Let us consider the signal s(t) equal to the sum of n components Sⱼ(t):

$$s ( t ) = {\sum }_{j = 1}^{n} {s}_{j} ( t ) .$$

The adapted time-frequency transform according to the invention must verify the following relation

$${T}_{s} ( t , ω ) = {\sum }_{j = 1}^{n} {W}_{{s}_{j}} ( t , ω ) ,$$

with Wₛ_{ⱼ}(t,ω) the Wigner-Ville transform of the signal sⱼ(t).

To construct this transform, let us consider the subset Sₚ, composed of the

$$p = [ \frac{n}{2} ]$$

nth roots of unity that are equal to

$${z}_{q} = {e}^{j \frac{2 q π}{n}} , q = 1 … [ \frac{n}{2} ] ,$$

where [ ] denotes the integer part operator.

Based on these p roots and on the signal s(t), it is possible to construct n·p intermediate signals denoted with X_{iq} varying from 1 to n and q varying from 1 to p, which will be used in the calculation of the adapted time-frequency transform.

$${X}_{iq} ( t ) = {z}_{q} \cdot s ( {t}_{i} ) δ ( t - {t}_{i} ) + {\sum }_{j = 1 , j \neq i}^{n} s ( {t}_{j} ) δ ( t - {t}_{j} ) \qquad ( 16 )$$

When the signal s(t) is digitized, the relation (16) can also be written in the following form:

$${X}_{iq} ( t ) = {z}_{q} \cdot {s}_{i} \cdot δ ( t - {t}_{i} ) + {\sum }_{j = 1 , j \neq i}^{n} {s}_{j} \cdot δ ( t - {t}_{j} ) ,$$

where sᵢ for i varying from 1 to n are the samples of the digitized signal s(t). The signal s(t) can then be considered as the sum of the n components sᵢ. δ(t−tᵢ) for i varying from 1 to n. δ(t) is the time-domain Dirac function. The constructed intermediate signals are a linear combination of the components.

The following calculations are similar to those already described for the examples with n=2 or 3 components.

The multiplication of each intermediate signal by its conjugate results in the relation (17):

$${X}_{iq} \cdot \overline{{X}_{iq}} = {\vert {z}_{q} \vert}^{2} + {s}_{i} \overline{{s}_{i}} + {\sum }_{j = 1 , j \neq i}^{n} {s}_{j} \overline{{s}_{j}} + {z}_{q} \cdot {\sum }_{j = 1 , j \neq i}^{n} {s}_{i} \overline{{s}_{j}} + \overline{{z}_{q}} \cdot {\sum }_{j = 1 , j \neq i}^{n} {s}_{j} \overline{{s}_{i}} + {\sum }_{j = 1 , j \neq i}^{n} {\sum }_{k = 1 , k \neq i , j}^{n} {s}_{j} \overline{{s}_{k}} \qquad ( 17 )$$

For a given root of index q, the terms X_{iq}· X̅_̅{̅i̅q̅}̅ are summed, knowing that |z_{q}|²=1 whatever the value of q, and we arrive at the relation (18):

$${\sum }_{i = 1}^{n} {X}_{iq} \cdot \overline{{X}_{iq}} = n \cdot {\sum }_{j = 1}^{n} {s}_{j} \overline{{s}_{j}} + {z}_{q} \cdot {\sum }_{i , j = 1 , i \neq j}^{n} {s}_{i} \overline{{s}_{j}} + \overline{{z}_{q}} \cdot {\sum }_{i , j = 1 , i \neq j}^{n} {s}_{i} \overline{{s}_{j}} + ( n - 2 ) {\sum }_{i , j = 1 , i \neq j}^{n} {s}_{i} \overline{{s}_{j}} \qquad ( 18 )$$

Finally, the relation (18) is summed over the set of values of q to arrive at the relation (19):

$${\sum }_{q = 1}^{P} ( {\sum }_{i = 1}^{n} {X}_{iq} \cdot \overline{{X}_{iq}} ) = n \cdot P \cdot {\sum }_{j = 1}^{n} {s}_{j} \overline{{s}_{j}} + ( {\sum }_{q = 1}^{P} ( {z}_{q} + \overline{{z}_{q}} + n - 2 ) ) \cdot ( {\sum }_{i , j = 1 , i \neq j}^{n} {s}_{j} \overline{{s}_{j}} ) \qquad ( 19 )$$

It is then advisable to distinguish the cases where n is even or odd. Indeed, if n is odd, no root z_{q} exists, belonging to the set Sₚ of the nth roots of unity, that is equal to its conjugate. Thus, the following relation can be established:

$$1 + {\sum }_{q = 1}^{P} ( {z}_{q} + \overline{{z}_{q}} ) = 0$$

and the relation (19) is simplified to arrive at the relation (20):

$${\sum }_{q = 1}^{P} ( {\sum }_{i = 1}^{n} {X}_{iq} \cdot \overline{{X}_{iq}} ) = n \cdot P \cdot {\sum }_{j = 1}^{n} {s}_{j} \overline{{s}_{j}} + ( P \cdot ( n - 2 ) - 1 ) \cdot ( {\sum }_{i , j = 1 , i \neq j}^{n} {s}_{j} \overline{{s}_{j}} ) \qquad ( 20 )$$

On the other hand, if n is even, a value q exists for which z_{q} is equal to its conjugate and to −1. In this case

$$1 + {\sum }_{q = 1}^{P} ( {z}_{q} + \overline{{z}_{q}} ) - 1 = 0$$

and equation (19) is simplified to arrive at the relation (21):

$${\sum }_{q = 1}^{P} ( {\sum }_{i = 1}^{n} {X}_{iq} \cdot \overline{{X}_{iq}} ) = n \cdot P \cdot {\sum }_{j = 1}^{n} {s}_{j} \overline{{s}_{j}} + ( P \cdot ( n - 2 ) - 2 ) \cdot ( {\sum }_{i , j = 1 , i \neq j}^{n} {s}_{j} \overline{{s}_{j}} ) \qquad ( 21 )$$

Finally, knowing that

$$s ( t ) \cdot \overline{s ( t )} = {\sum }_{j = 1}^{n} {s}_{j} \overline{{s}_{j}} + {\sum }_{j = 1 , i \neq j}^{n} {s}_{j } \overline{{s}_{j}} ,$$

the expression of the adapted time-frequency transform according to the invention is derived therefrom, in the case where n is even (relation (22)) and n is odd (relation (23)):

$$\begin{matrix}\begin{matrix}{T}_{s} ( t , ω ) = {\sum }_{j = 1}^{n} {W}_{{s}_{j}} ( t , ω ) \\ = \frac{1}{2 \cdot ( P + 1 )} \{ {\sum }_{q = 1}^{P} {\sum }_{i = 1}^{n} {W}_{{X}_{iq}} - [ P \cdot ( n - 2 ) - 2 ] \cdot {W}_{s} \}\end{matrix} & ( 22 ) \\ \begin{matrix}{T}_{s} ( t , ω ) = {\sum }_{j = 1}^{n} {W}_{{s}_{j}} ( t , ω ) \\ = \frac{1}{2 P + 1} \{ {\sum }_{q = 1}^{P} {\sum }_{i = 1}^{n} {W}_{{X}_{iq}} - [ P \cdot ( n - 2 ) - 1 ] \cdot {W}_{s} \}\end{matrix} & ( 23 )\end{matrix}$$

### Application of the Adapted Time-Frequency Transform to Detecting Soft Faults in a Cable.

A description will follow of the series of steps of implementation of the method of reflectometry according to the invention for detecting one or a plurality of soft faults in a cable.

In a first step, a reflectometry signal is injected into the cable to be diagnosed. This signal reflects off the singularities of the cable to an acquisition point. The method according to the invention is applied to this reflected signal s(t) which is a multi-component signal from the moment that at least one fault exists on the cable to be tested. However, the number and the time-based positions of the components are not known. After acquisition over a given time period, the signal s(t) is digitized to produce a number n of samples sᵢ. The signal s(t) can be seen as the sum of n components corresponding to the n samples:

$$s ( t ) = {\sum }_{i = 1}^{n} s ( {t}_{i} ) δ ( t - {t}_{i} ) = {\sum }_{i = 1}^{n} {s}_{i} . δ ( t - {t}_{i} ) .$$

Depending on the parity of n, the adapted time-frequency transform is then calculated Tₛ(t,ω) using the relation (22) or (23). This calculation initially involves the construction of the n·p intermediate signals X_{iq} based on the relation (16), then of the Wigner-Ville transform of each of these intermediate signals as well as that of the signal s(t).

The result obtained after application of the transform Tₛ(t,ω) according to the invention then makes it possible to detect and to locate the components of the signal s(t) that correspond to reflections off singularities of the cable under test. Advantageously, it is possible to apply to this result a normalized time-frequency cross-correlation function in order to further improve the discrimination of faults. By using the adapted time-frequency transform Tₛ(t,ω) instead and in place of a conventional Wigner-Ville transform, the cross terms are suppressed, which makes it possible to improve the reliability of the detection and of the location of the cable faults producing reflections of low amplitudes.

A description will follow of a second variant embodiment of the invention that has the advantage of reducing the number of calculations to be executed to construct the adapted time-frequency transform according to the invention.

As mentioned above, the calculation of Tₛ(t,ω) requires an intermediate calculation of a number equal to p·n+1 of Wigner-Ville transforms. In a second variant, the invention makes it possible to limit this number to n+1.

For this, the form and the number of intermediate signals X_{iq} are modified. Now, still based on the samples sᵢ of the reflected signal in the cable to be tested, a number n of intermediate signals, Xᵢ, are constructed, with i varying from 1 to n such that

$${X}_{i} ( t ) = j . {s}_{i} . δ ( t - {t}_{i} ) + {\sum }_{k = 1 , k \neq i}^{n} {s}_{k} . δ ( t - {t}_{k} ) ,$$

with j the complex number such that j²=−1.

By multiplying each signal Xᵢ by its conjugate, relation (24) is obtained:

$${X}_{i} . \overline{{X}_{i}} = {\sum }_{k = 1}^{n} {s}_{k} . \overline{{s}_{k}} + j . {\sum }_{k = 1 , k \neq i}^{n} ( {s}_{i} \overline{{s}_{k}} - {s}_{k} \overline{{s}_{i}} ) + {\sum }_{k = 1 , k \neq i}^{n} {\sum }_{q = 1 , q \neq i , k}^{n} {s}_{k} \overline{{s}_{q}} \qquad ( 24 )$$

By summing all these terms the relation (25) is obtained:

$${\sum }_{i = 1}^{n} {X}_{i} . \overline{{X}_{i}} = n . {\sum }_{k = 1}^{n} {s}_{k} . \overline{{s}_{k}} + j . {\sum }_{i = 1}^{n} {\sum }_{k = 1 , k \neq i}^{n} ( {s}_{i} \overline{{s}_{k}} - {s}_{k} \overline{{s}_{i}} ) + ( n - 2 ) . {\sum }_{i = 1}^{n} {\sum }_{k = 1 , i \neq k}^{n} {s}_{i} \overline{{s}_{k}} = n . {\sum }_{k = 1}^{n} {s}_{k} . \overline{{s}_{k}} + ( n - 2 ) {\sum }_{i = 1}^{n} {\sum }_{k = 1 , i \neq k}^{n} {s}_{i} \overline{{s}_{k}} \qquad ( 25 )$$

Finally, the expression of the adapted time-frequency transform is obtained, valid for n>2:

$${T}_{s} ( t , ω ) = {\sum }_{j = 1}^{n} {W}_{{s}_{j}} ( t , ω ) = \frac{1}{n - 1} \{ {\sum }_{i = 1}^{n} {W}_{{X}_{i}} - ( n - 2 ) . {W}_{s} \} \qquad ( 26 )$$

By way of illustrative example, when n=2, for a signal s(t) having two components s₁ and s₂, the intermediate signals are X₁=j·s₁+s₂ and X₂=s₁+j·s₂. By calculating the Wigner-Ville transforms of each of these signals the following relations are achieved:

Wₓ_{₁}(t,ω)=Wₛ_{₁}(t,ω)+Wₛ_{₂}(t,ω)+j·(Wₛ_{₁}ₛ_{₂}(t,ω)−Wₛ_{₂}ₛ_{₁}(t,ω))

Wₓ_{₂}(t,ω)=Wₛ_{₁}(t,ω)+Wₛ_{₂}(t,ω)−j·(Wₛ_{₁}ₛ_{₂}(t,ω)−Wₛ_{₂}ₛ_{₁}(t,ω))

The adapted transform

$${T}_{s} ( t , ω ) = \frac{1}{2} ( {W}_{{x}_{1}} ( t , ω ) + {W}_{{x}_{2}} ( t , ω ) ) = {W}_{{s}_{1}} ( t , ω ) + {W}_{{s}_{2}} ( t , ω )$$

makes it possible to suppress the cross terms inherent to the Wagner-Ville transform.

In both variant embodiments of the invention, the adapted time-frequency transform Tₛ(t,ω) is set equal to a linear combination of the Wigner-Ville transforms of the intermediate signals Xᵢ or X_{iq} and of the signal S and is constructed so that it is furthermore equal to the sum of the Wigner-Ville transforms of the components Sⱼ of the signal S.

In both variant embodiments of the invention, the intermediate signals can be expressed in the form

$${X}_{i ( q )} ( t ) = α . {s}_{i} . δ ( t - {t}_{i} ) + {\sum }_{j = 1 , j \neq i}^{n} {s}_{j} . δ ( t - {t}_{j} )$$

for i varying from 1 to the number n of samples of the signal S(t), with α a weighting coefficient equal to the complex number j the square of which is equal to −1 or equal to an nth root of unity, depending on the embodiment chosen.

In another variant embodiment of the invention, the back propagated and digitized signal is denoised beforehand, for example by applying to it a method of denoising by wavelets or any other known method making it possible to improve the signal-to-noise ratio.

In another variant embodiment of the invention, the digitized signal is sub-sampled so as to retain only a part of the available samples for the construction of the intermediate signals. Thus, the number of calculations to be implemented is limited, although this variant has the drawback of inferior discrimination of faults in the time domain.

In another variant embodiment of the invention, the signal s(t) can be decomposed in a different way to simple digitization. Generally speaking, any signal s(t) can indeed be decomposed into a convergent series of Gaussian functions:

$$s ( t ) = {\sum }_{i = 1}^{N} {α}_{i} . {g}_{i} ( t ) ,$$

with N an integer large enough to ensure a correct convergence of the series, αᵢ real coefficients and gᵢ(t) a set of Gaussian functions. In this case, the method according to the invention is applied in an identical manner, the samples sᵢ of the digitized signal being replaced with the components αᵢ·gᵢ(t) in the definition of the intermediate signals Xᵢ,X_{iq}.

The signal s(t) can also be decomposed using a time window w(t) of time length T, centered on 0 and such that ∫_{-∞}^{+∞}|w(t)|²=1. The signal s(t) is then decomposed in the following way:

$$s ( t ) = {\sum }_{i = 1}^{N} w ( t - {t}_{i} ) . s ( t ) .$$

In other words, the components of the signal s(t) are, in this case, equal to the weighting of the signal itself by the window w(t) centered on the times tᵢ.

We will now describe the implementation of the method according to the invention in a reflectometry system as well as the results obtained using the invention on the improvement of the detection of soft faults in a cable.

FIG. 1 shows a diagram of an example reflectometry system according to the invention.

A cable to be tested 104 has a soft fault 105 at any distance from any end 106 of the cable.

The reflectometry system 101 according to the invention comprises an electronic component 111 of integrated circuit type, such as a programmable logic circuit, for example an FPGA, or a microcontroller, suitable for executing two functions. On the one hand, the component 111 makes it possible to generate a reflectometry signal s(t) to be injected into the cable 104 under test. This digitally generated signal is then converted via a digital-to-analog converter 112 then injected 102 into one end 106 of the cable. The signal s(t) propagates in the cable and is reflected off the singularity generated by the fault 105. The reflected signal is backpropagated to the injection point 106 then captured 103, digitally converted via an analog-to-digital converter 113, and transmitted to the component 111. The electronic component 111 is furthermore suitable for executing the steps of the method according to the invention described above in order to produce, based on the received signal s(t), a time-frequency reflectogram that can be transmitted to a processing unit 114, of computer, PDA or other type, to display the results of the measurements on a human-machine interface.

The system 101 shown in FIG. 1 is a completely non-limiting example embodiment. In particular the two functions executed by the component 111 can be separated into two distinct components or devices, for example a first device for generating and injecting the reflectometry signal into the cable 104 to be tested, and a second device for acquiring and processing the reflected signal. In such a situation, the method according to the invention is implemented in the second device for acquiring and processing the reflected signal.

FIG. 2 shows, on a time-voltage diagram, the amplitude of the backpropagated signal s(t) when the injected reflectometry signal is a single Gaussian pulse, and without the implementation of the invention.

This signal is a multi-component signal since it is the sum of the pulse reflected off the input mismatch 201, off the termination of the cable 202 and off the soft fault 203. It will be noted that the amplitude 203 of the signal reflected off the soft fault is low and therefore hard to detect.

FIG. 3 illustrates, on a time-frequency diagram, the result obtained after applying the conventional Wigner-Ville transform to the signal represented in the time domain in FIG. 2. The two frequency peaks corresponding to the input mismatch 301 of the cable and to the reflection of the signal off the end of the cable 302 can be seen. The amplitude of the peak 303 related to the reflection off the soft fault is, in contrast, masked by the appearance of an unwanted peak 304 resulting from the cross term induced by the quadratic character of the Wigner-Ville transform. This cross term is due to the interaction between the pulse reflected off the termination of the cable and that reflected off the input mismatch.

FIG. 4 shows, on a timing diagram, the result of the application of a normalized time-frequency cross-correlation function to the time-frequency signal in FIG. 3. This result 401 still shows the existence of an unwanted peak 404 of the same amplitude as the peak 405 associated with the soft fault. FIG. 3 also shows the same result 402 when an adapted Wigner-Ville transform of the prior art, described in “The use of the pseudo Wigner Ville Transform for detecting soft defects in electric cables, Maud Franchet et al.” is used as a replacement for the conventional Wigner-Ville transform. In this case, the amplitude of the peak 404 associated with the cross term is reduced but not suppressed. Finally, a third result 403 is shown on the same diagram in FIG. 4. It corresponds to the application of the time-frequency transform according to the invention. It will be noted that the influence of the cross terms is totally suppressed this time. The amplitude peak 405 associated with the soft fault can be detected without ambiguity and with increased precision of location, the width of the reflected pulse being less than for the solutions of the prior art as the curve 403 of FIG. 4 also illustrates. The invention also has the advantage of enabling a better location of the useful terms because the latter are not polluted by the presence of interfering terms. The risk of false detection is suppressed.

1. A reflectometry method for detecting at least one fault in a cable, comprising a step of acquiring a signal S(t) injected into said cable and reflected off at least one singularity of said cable, and furthermore comprising the following steps:
decomposing said reflected signal S(t) into a plurality of time components sᵢ(t),
constructing, from said time components, a plurality of intermediate signals, (X_{iq}(t),Xᵢ(t)) using the following relation
$${X}_{i ( q )} ( t ) = α . {s}_{i} . δ ( t - {t}_{i} ) + {\sum }_{j = 1 , j \neq i}^{n} {s}_{j} . δ ( t - {t}_{j} ) ,$$
for i varying from 1 to the number n of samples of the signal S(t), with α a weighting coefficient equal to the complex number j the square of which is equal to −1 or equal to an nth root of unity
$${z}_{q} = {e}^{j \frac{2 q π}{n}} ,$$
with q varying from 1 to the integer part of n/2,
calculating the Wigner-Ville transform, W_{Xi}, W_{S}, of each of said intermediate signals and of said reflected signal,
calculating a time-frequency transform Tₛ(t,ω) equal to the sum of the Wigner-Ville transforms of said time components sᵢ(t), based on a linear combination of said Wigner-Ville transforms of each of said intermediate signals W_{Xi} and of said reflected signal W_{S},
detecting and locating the maxima of said time-frequency transform Tₛ(t,ω), and deriving the existence and the location of the sought faults therefrom.

2. The reflectometry method of claim 1, wherein, when said weighting coefficient α is equal to an nth root of unity, the time-frequency transform Tₛ(t,ω) is given by the relation
$${T}_{s} ( t , ω ) = \frac{1}{2. ( P + 1 )} \{ {\sum }_{q = 1}^{P} {\sum }_{i = 1}^{n} {W}_{{X}_{iq}} - [ P . ( n - 2 ) - 2 ] . {W}_{s} \}$$
if n is even and by the relation
$${T}_{s} ( t , ω ) = \frac{1}{2. P + 1} \{ {\sum }_{q = 1}^{P} {\sum }_{i = 1}^{n} {W}_{{X}_{iq}} - [ P . ( n - 2 ) - 1 ] . {W}_{s} \}$$
if n is odd, with P an integer number equal to the integer part of n/2, W_{Xiq} the Wigner-Ville transform of the intermediate signal X_{iq}(t) and W_{S} the Wigner-Ville transform of the reflected signal S(t).

3. The reflectometry method of claim 1, wherein, when said weighting coefficient α is equal to the complex number j the square of which is equal to −1, the time-frequency transform Tₛ(t,ω) is given by the relation
$${T}_{s} ( t , ω ) = \frac{1}{n - 1} \{ {\sum }_{i = 1}^{n} {W}_{{X}_{i}} - ( n - 2 ) . {W}_{s} \} ,$$
with n an integer strictly greater than two, W_{Xi} the Wigner-Ville transform of the intermediate signal Xᵢ(t) and W_{S} the Wigner-Ville transform of the reflected signal S(t).

4. The reflectometry method of claim 1, wherein the decomposition of the signal S(t) into a plurality of time components sᵢ(t) is carried out by sub-sampling.

5. The reflectometry method of claim 1, wherein the decomposition of the signal S(t) into a plurality of time components sᵢ(t) is carried out by decomposition of said signal into a linear combination of Gaussian functions.

6. The reflectometry method of claim 1, wherein the decomposition of the signal S(t) into a plurality of time components sᵢ(t) is carried out using the following relation:
$$s ( t ) = {\sum }_{i = 1}^{N} w ( t - {t}_{i} ) . s ( t ) ,$$
where w is a time window of given length applied to said signal s(t) at a plurality of successive times tᵢ.

7. The reflectometry method of claim 1, comprising a step of calculating the normalized time-frequency cross-correlation function applied to the result of the time-frequency transform Tₛ(t,ω).

8. The reflectometry method of claim 1, wherein said reflected signal S(t) is denoised beforehand after its acquisition.

9. A device for processing a reflectometry signal including means for acquiring a signal reflected off at least one singularity of a cable and processing and analyzing means adapted to implement the reflectometry method according to claim 1.

10. A reflectometry system comprising means for injecting a signal S(t) into a cable to be tested, means for acquiring said signal reflected off at least one singularity of said cable, means for analog-to-digital conversion of said reflected signal, and furthermore comprising processing and analyzing means adapted to implement the reflectometry method according to claim 1.
